(19) United States
(12) Patent Application Publication
(10) Pub. No.: US 2018/0095131 A1
(43) Pub. Date: Apr. 5, 2018

(54) METHOD OF DIAGNOSING A MAGNETIZATION FAULT OF A PERMANENT MAGNET MOTOR

(71) Applicant: HYUNDAI MOTOR COMPANY, Seoul (KR)

(72) Inventors: Ji Wan Cha, Incheon (KR); Gu Bae Kang, Yongin-si (KR); Jae Sang Lim, Suwon-si (KR); Seong Yeop Lim, Seoul (KR); Young Un Kim, Suwon-si (KR)

(73) Assignee: HYUNDAI MOTOR COMPANY, Seoul (KR)

(21) Appl. No.: 15/394,456

(22) Filed: Dec. 29, 2016

(30) Foreign Application Priority Data
Oct. 5, 2016 (KR) 10-2016-0128198

(51) Int. Cl. G01R 31/34

(52) U.S. Cl. CPC G01R 31/34

(57) ABSTRACT

A method of diagnosing a magnetization fault of a permanent magnet motor is provided. The method includes calculating a resolver offset value for offset correction of a resolver mounted at the motor, calculating a correction deviation, namely, a difference value between the calculated resolver offset value and a predetermined reference value to compare the calculated correction deviation to an allowable error, comparing a difference value between the calculated correction deviation and a predetermined phase difference value of reverse magnetization of the permanent magnet to the allowable error when the calculated correction deviation is more than the allowable error, and determining that the motor is in a reversely magnetized state when the difference value between the calculated correction deviation and the predetermined phase difference value of reverse magnetization of the permanent magnet is equal to or less than the allowable error.

### CROSS-REFERENCE TO RELATED APPLICATION

This application claims priority to Korean Patent Application No. 10-2016-0128198, filed on Oct. 5, 2016, in the Korean Intellectual Property Office, the entire disclosure of which is incorporated herein by reference.

### BACKGROUND

### 1. Field of the Disclosure

The present disclosure relates to a method of diagnosing a magnetization fault of a permanent magnet motor and, more particularly, to a method of diagnosing a magnetization fault capable of detecting a reversely magnetized state of a permanent magnet of the motor.

### 2. Description of Related Art

An electric motor is used as a driving source for driving a green car, such as an electric vehicle (EV), a hybrid electric vehicle (HEV), or a fuel cell electric vehicle (FCEV). A green car may replace an internal combustion engine car.

An interior permanent magnet synchronous motor (IPMSM) is used as an electric motor (e.g., a driving motor), i.e. the driving source of the green car.

The green car includes an inverter system for driving and controlling the motor. A resolver is used as a position sensor for detecting an absolute angular position θ of a rotor of the motor, which is used to control the motor.

A coordinate system is determined at a flux position of the motor after synchronization in order to control a vector of the motor in the green car. To this end, the absolute angular position is read with regard to the rotor of the motor.

The resolver is used to detect the absolute angular position of the motor rotor. Each phase of the rotor of the motor is accurately sensed through the resolver to control motor speed and torque for driving the green car.

FIG. 1 is a schematic illustration of a configuration of a motor and a resolver.

Reference numeral 2 indicates a rotor of the motor 1. Reference numeral 3 indicates a shaft (or a central shaft of the rotor) of the motor 1, and reference numeral 4 indicates a stator of the motor 1. Reference numeral 11 indicates a rotor of a resolver and reference numeral 13 indicates a stator of the resolver.

As illustrated, the resolver includes the rotor 11 and the stator 13. The rotor 11 of the resolver may be mounted at the shaft 3 of the motor 1, and the stator 13 of the resolver may be mounted at the stator 4 of the motor 1.

Furthermore, a coil wound on the rotor 11 and the stator 13 of the resolver is wound for magnetic flux distribution to be a sine wave with respect to angles.

When the rotor 11 of the resolver is rotated by the rotor 3 of the motor 1 in the state that an excitation signal (M REZ+, M REZ−) is applied at a first coil (e.g., an input terminal) wound on the rotor 11 of the resolver, a magnetic coupling coefficient is changed. As a result, a signal in which an amplitude of each carrier is changed is generated at a second coil (e.g., an output terminal) wound on the stator 13 of the resolver. The coil is wound for the signal to be changed to have cosine (cos) and sine (sin) shapes according to a rotation angle 8 of the rotor 2 of the motor and the rotor 11 of the resolver. Referring to FIGS. 2 and 3, an excitation voltage generation circuit 29 of a control unit 20 (e.g., a power control unit (PCU)) generates a sine-shape voltage signal having a constant amplitude, i.e., an excitation signal (U₀: M_REZ+, M_REZ−). As a result, the signal is applied to the first coil (referred to as a reference coil) wound on the rotor 11 of the resolver 10.

When the excitation signal U₀ is applied to the first coil 12 of the resolver, outputs REZS1 and REZS3 (i.e., a cosine-shape voltage signal U₁) and outputs REZS2 and REZS4 (i.e., a sine-shape voltage signal U₂) are output from second coils 14 and 15 (referred to as an output coil) wound on the stator (not shown).

A magnetic flux interlinkage is periodically changed based on the change of reluctance due to rotation of the rotor 11 of the resolver. Amplitudes of the voltage signals U₁ and U₂ output from the second coils of the stator of the resolver are changed based on a rotation angle θ of the motor 1.

As illustrated in FIG. 3, peak points of the voltage signals U₁ and U₂ output from the resolver 10 are connected to an envelope through a resolver-to-digital converter (RDC) 21 to be converted into a cosine signal and a sine signal which indicate an absolute angular position θ (a position angle) of the motor at the control unit 20.

FIG. 4 illustrates a magnetization state of the rotor in accordance with a polarity arrangement of a permanent magnet in an interior permanent magnet synchronous motor (IPMSM). FIG. 4 shows a comparison of the motors in a normal magnetization state and in an abnormal reverse magnetization state.

As illustrated, the reverse magnetization state of the permanent magnet of the motor indicates that the polarity of the permanent magnet is reversed, namely, an N pole and an S pole are reversed relative to the normal magnetization state.

Additionally, the reversely magnetized permanent magnet 5 has an electrical phase difference of 180 degrees relative to the normal magnetization.

The abnormal reverse magnetization state may be generated by a mistake of an operator or a process error during manufacture of the motor.

Upon control of a direct quadrature (d-q) current vector, the interior permanent magnet synchronous motor includes a controllable region (e.g., second and third quadrants of a d-q control plane) and an uncontrollable region. When the current vector control of the motor including the permanent magnet in the abnormal reverse magnetization state is performed in a conventional manner, the current is applied to the uncontrollable region in the d-q control plane.

When applying a current command to the reversely magnetized motor, a current operating point is determined at the uncontrollable region such that it is impossible to control the motor. For instance, control problems occur. In some cases, it is impossible to control weak magnetic flux at a middle/high speed region.

When a driving motor functioning as a driving source of a vehicle is in a reverse magnetization state, it is impossible to drive the vehicle due to the impossibility of controlling the motor.

Hardware such as a power module and a capacitor in an inverter may be damaged due to an increase of counter electromotive force of the motor by the permanent magnet having increased magnetization at high speed.

A motor having a reversely magnetized permanent magnet is accordingly a defective product generated during the manufacture process. As a result, it is useful to properly check the motor. When reverse magnetization defects occur, a decrease in productivity disadvantageously occurs.

When a reversely magnetized motor is mounted in a vehicle, an operator expends effort and time for the removal, replacement, dismantlement, and analysis of the motor. Expenses for mounting a new motor and expenses for disposal of the defective motor are also incurred.

### SUMMARY OF THE DISCLOSURE

A method of diagnosing a magnetization fault of a permanent magnet motor is provided. The method is capable of detecting a reverse magnetization state of the motor using a procedure (e.g., a logic procedure) rather than added hardware.

In accordance with one aspect, a method of diagnosing a magnetization fault of a permanent magnet motor is provided. The method includes a) calculating a resolver offset value for offset correction of a resolver mounted at the motor, b) calculating a correction deviation, e.g., a difference value between the calculated resolver offset value and a predetermined design reference value to compare the calculated correction deviation to a design allowable error, c) comparing a difference value between the calculated correction deviation and a predetermined phase difference value of reverse magnetization of the permanent magnet to the design allowable error when the calculated correction deviation is more than the design allowable error, and d) determining that the motor is in the reversely magnetized state when the difference value between the calculated correction deviation and the predetermined phase difference value of reverse magnetization of the permanent magnet is equal to or less than the design allowable error.

The phase difference value of reverse magnetization may be determined to be 180 degrees.

In step a), the resolver offset value may be calculated by adding a resolver offset correction value calculated in a zero current state of the motor, in which direct (d)-axis and quadrature (q)-axis currents are controlled to be zero current, to an original resolver offset value.

In step b), the calculated correction deviation may be compared to the design allowable error, when the correction deviation is equal to or less than the design allowable error, the resolver offset value calculated in step a) may be used to perform resolver offset correction.

In step d), when the permanent magnet of the motor is determined to be in the reversely magnetized state, a new resolver offset value may be calculated by adding a resolver offset correction value calculated in a zero current state of the motor, in which d-axis and q-axis currents are controlled to be zero current, and the phase difference value of reverse magnetization of the permanent magnet to an original resolver offset value, and the new resolver offset value may be used to correct the resolver offset.

The terms “vehicle”, “vehicular” and other similar terms used herein are inclusive of motor vehicles in general, such as passenger automobiles including sport utility vehicles (SUV), buses, trucks, various commercial vehicles, watercraft including a variety of boats and ships, aircraft, and the like, and include hybrid vehicles, electric vehicles, plug-in hybrid electric vehicles, hydrogen-powered vehicles and other alternative fuel vehicles (e.g., fuels derived from resources other than petroleum). As referred to herein, a hybrid vehicle is a vehicle that has two or more sources of power, for example both gasoline-powered and electric-powered vehicles.

### BRIEF DESCRIPTION OF THE DRAWINGS

The above and other features of the present disclosure will now be described in detail with reference to certain embodiments illustrated in the accompanying drawings, which are provided by way of illustration only, and thus are not limitative of the present disclosure, and wherein:

FIG. 1 is a schematic illustration of a configuration of a motor and a resolver;

FIG. 2 is an illustration of a general resolver and a general control unit;

FIGS. 3A to 3C are illustrations of an input signal and an output signal of the general resolver;

FIG. 4 is an illustration of a polarity arrangement of a permanent magnet according to a magnetization direction of a rotor of the motor;

FIG. 5 is a block diagram illustrating a connection state between an inverter system and the motor;

FIGS. 6 and 7 are illustrations of known resolver offset correction;

FIG. 8 is an illustration of a method of correcting reverse magnetization of a rotor of a permanent magnet using a resolver offset according to one embodiment;

FIG. 9 is an illustration of vector control using current driving point transfer effect according to one embodiment; and

FIG. 10 is a flowchart illustrating a process of detection and correction of reverse magnetization according to one embodiment.

It should be understood that the appended drawings are not necessarily to scale, and may present a simplified representation of aspects of the disclosure. The specific features of the present disclosure, including, for example, specific dimensions, orientations, locations, and shapes will be determined in part by the particular intended application and use environment.

In the figures, reference numbers refer to same or equivalent parts or elements of the present disclosure throughout the several figures of the drawing.

### DETAILED DESCRIPTION

Reference will now be made in detail to various examples of the disclosed methods illustrated in the accompanying drawings and described below. The disclosed methods, however, are capable of being embodied in various different forms and are not limited to the examples described below.

Unless explicitly stated to the contrary, the word “comprise,” “comprises” or “comprising” used throughout the specification will not be understood as excluding other elements but rather to imply the possible inclusion of other elements.

The present disclosure relates to a method of diagnosing a magnetization fault of a permanent magnet motor and, more particularly, to a method of diagnosing a magnetization fault capable of detecting a reversely magnetized state of a permanent magnet of the motor.

The motor may be an interior permanent magnet synchronous motor (IPMSM) in which a permanent magnet is mounted at a rotor. A north (N) pole and a south (S) pole of the permanent magnet are alternately disposed at the rotor of the interior permanent magnet synchronous motor.

The motor may be a driving motor used as a driving source of a vehicle, such as a green car.

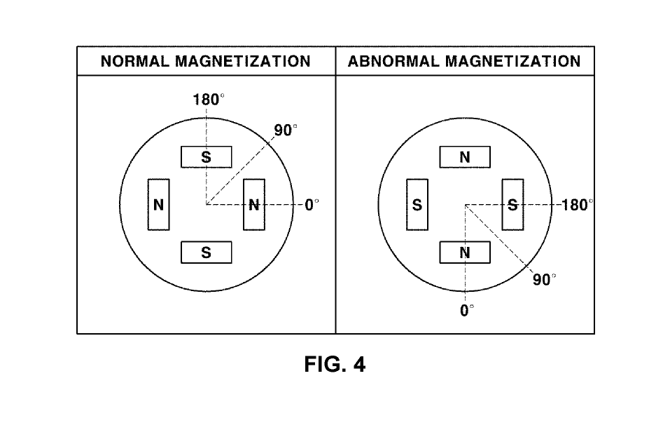

In some embodiments, the magnetization fault of the permanent magnet of the motor is a reverse magnetization of the permanent magnet. In the example of FIG. 4, a reverse magnetization state of the permanent magnet of the motor is a reverse arrangement of an N pole and an S pole relative to the normal magnetization state. The permanent magnet of the reversely magnetized motor has an electrical phase difference of 180 degrees relative to the permanent magnet of the normally magnetized motor.

Based on the foregoing characteristics, a reverse magnetization of the permanent magnet of the motor is detected using a position sensor mounted at the motor, that is, a voltage output signal of the resolver to detect an absolute angular position θ of the rotor.

A method of correcting an offset of the resolver is provided. The method corrects the offset using polarity arrangement characteristics of the permanent magnet of the motor upon detection of reverse magnetization of the permanent magnet of the motor.

A method of detecting a reverse magnetization of the permanent magnet of the motor is provided. The method corrects the offset of the resolver mounted at the reversely magnetized motor after detecting the reverse magnetization. As a result, it is possible to perform normal control on the reversely magnetized motor by correcting the offset of the resolver of the reversely magnetized motor.

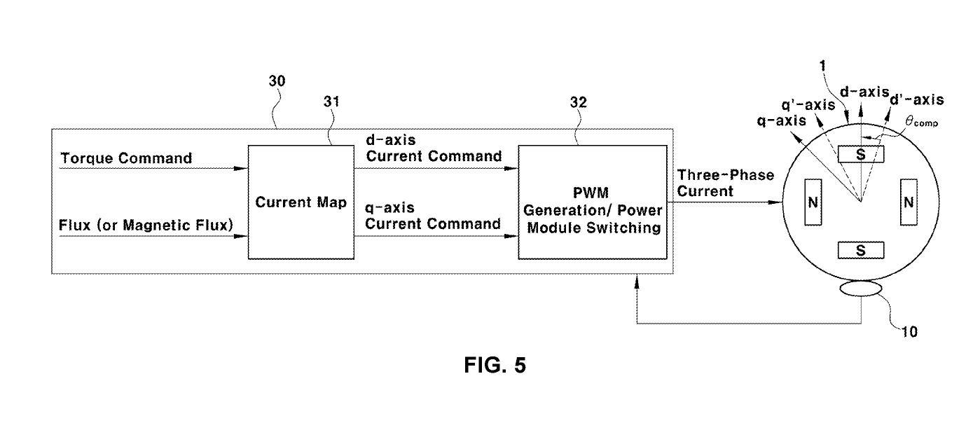

Referring to FIGS. 5 to 7, a known method of correcting a resolver offset will be described.

FIG. 5 is a block diagram illustrating a connection state between an inverter system 30 and a motor. A current command generator 31 in the inverter system 30 receives a torque command and rotation speed of the motor ωᵣₚₘ to generate a d-axis current command and a q-axis current command using a current map. A pulse width modulation (PWM) signal is generated in the inverter 32 according to the generated current commands to control switching of a power module in the inverter 32. Three-phase current applied to the motor is controlled by switching control of the power module.

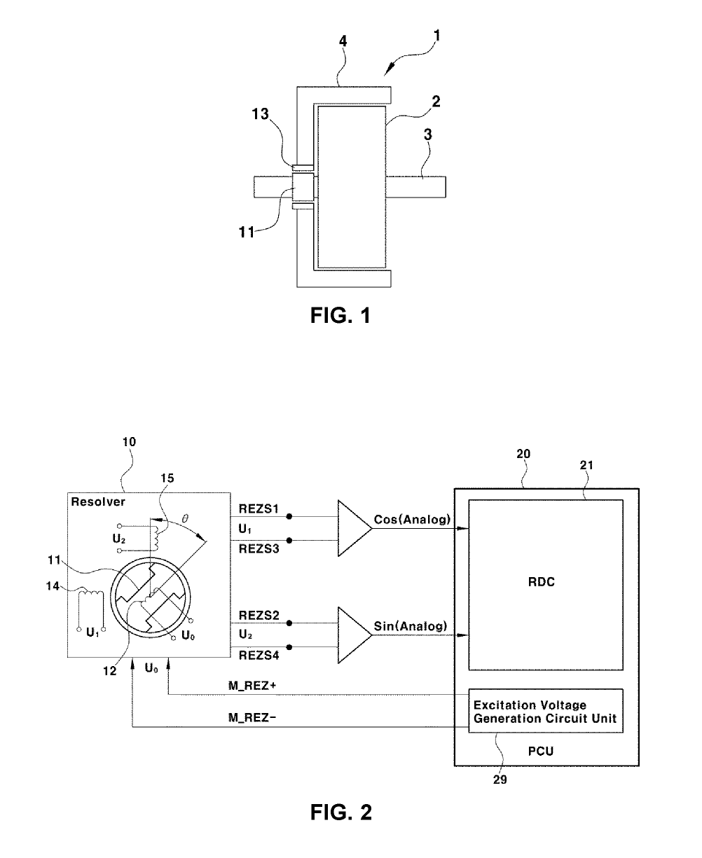

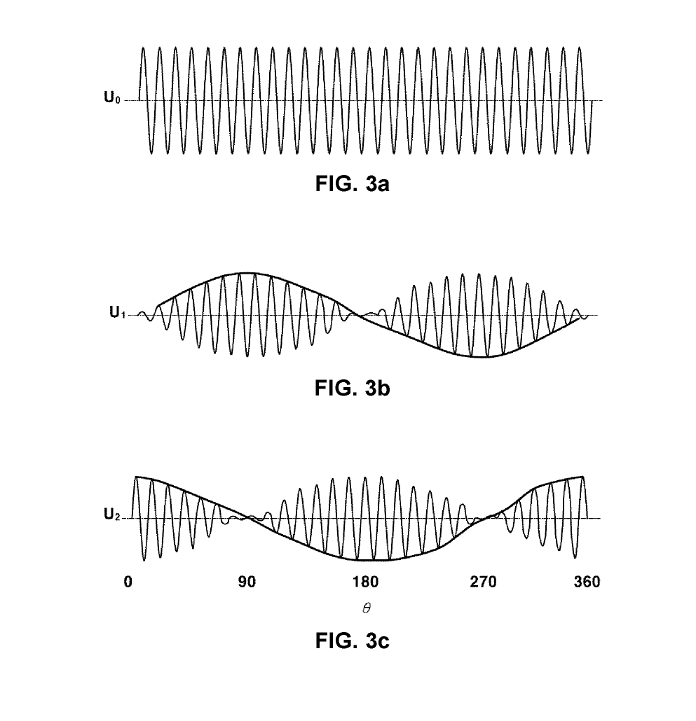

The resolver 10 mounted at the motor 1 is used to predict position, speed, and angle of a central axis of the rotor (e.g., a motor shaft). The resolver 10 includes a reference coil, i.e., a first coil 12 (FIG. 1), and output coils, i.e., second coils 14 and 15 (FIG. 1).

Accordingly, an excitation signal is applied to the reference coil of the resolver 10, and the speed and position of the rotor are estimated by a controller using a voltage output signal generated at the output coil.

However, various conditions, such as assembly tolerance between the motor 1 and the resolver 10 and position inaccuracy of the coil in the resolver, may generate a position offset between the rotor of the motor and the resolver. Unless the output signal of the resolver is corrected by the offset, it is impossible to reflect a precise position of the rotor upon control of the motor. Therefore, correction of the offset of the resolver is warranted.

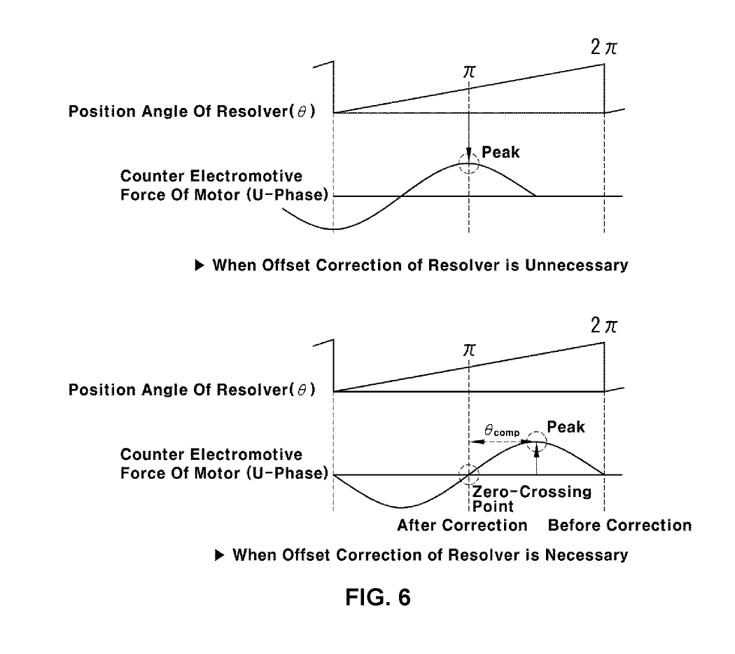

FIG. 6 illustrates the correction of the offset of the resolver. In order to control an ideal current vector of the motor, it is useful to precisely obtain information of an absolute angular position θ, i.e., information of a position angle of the rotor (e.g., a motor rotation angle).

In order to obtain precise information of the position angle of the rotor, after mounting the resolver, offset correction is performed. This is performed to correct an error caused by mechanical and electrical tolerance upon installation of the resolver. The current vector control reflecting a resolver offset value -offset and a correction value Q_{comp} is performed such that it is possible to control the motor speed and torque (before correction: d′-axis and q′-axis in FIG. 5).

In order to control the motor vector, as shown in FIG. 6, the position angle π of the resolver and a peak position of U-phase of a counter electromotive force of the motor are identical to each other. When the position angle π of the resolver and the peak position of U-phase of the counter electromotive force of the motor differ from each other, the difference (e.g., the offset) may be corrected using a procedure (e.g., a logic procedure).

As illustrated in FIG. 6, when the position angle π of the resolver and the peak position of U-phase of the counter electromotive force of the motor are identical, it is unnecessary to correct the offset of the resolver. When the position angle π of the resolver and the peak position of U-phase of the counter electromotive force of the motor are different, correction of the offset of the resolver is warranted.

Upon control of the motor vector, resolver offset correction is performed for a Vd-axis voltage of a synchronous coordinate to be 0 degrees. Upon control of the motor vector, the difference between the angles Vd and Vq of the synchronous coordinate is corrected by an angle difference.

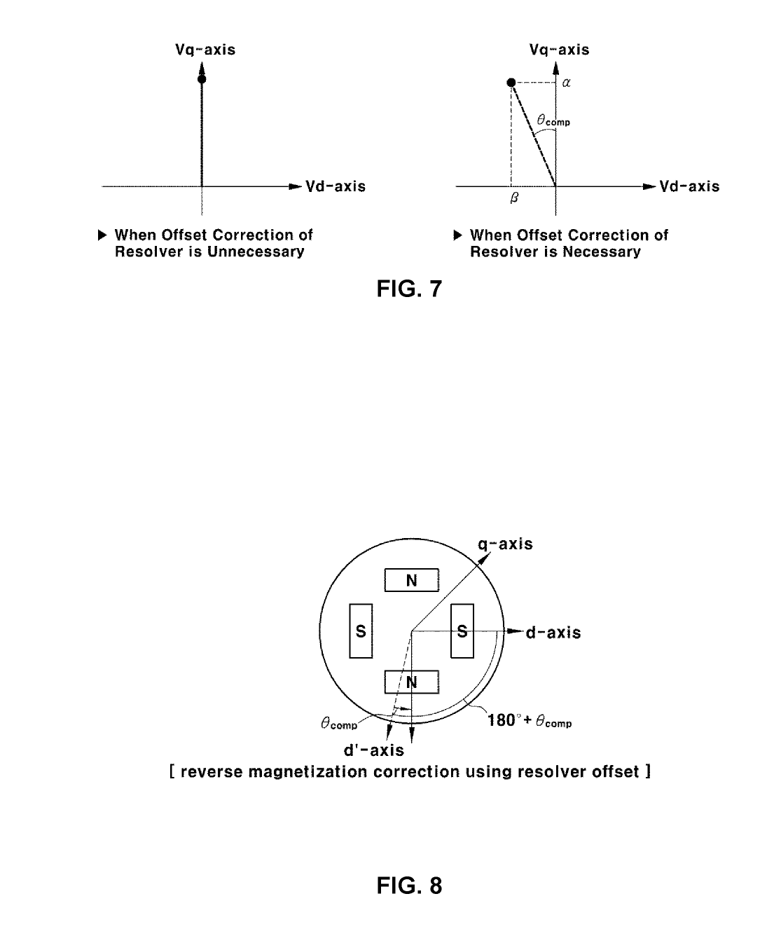

Furthermore, referring to FIG. 7, for example, when Vd=0 and Vq=α, there is no angle difference between Vd and Vq. As a result, it is unnecessary to correct the resolver offset. Alternatively, when Vd=β and Vq=α, an angle difference between Vd and Vq is θ_{comp} such that correction of the resolver offset is warranted.

Thus, in order to correct the resolver offset, the motor is controlled by zero (0) current and the resolver offset is corrected such that the d-axis voltage Vd of the synchronous coordinate becomes 0.

Upon correction of the resolver offset, the d-axis and q-axis currents are controlled to be zero current (Id=0, and Iq=0) such that the angle difference (θ_{comp}=tan⁻¹(α/β)) of Vd and Vq is calculated as a correction value θ_{comp} of the resolver offset. As shown below Equation 1, the calculated correction value θ_{comp} of the resolver offset is added to an original resolver offset value θ_{original}_{_}_{offset} to calculate a new revolver offset value θ_{new}_{_}_{offset}.

θ_{new}_{_}_{offset}=θ_{original}_{_}_{offset}+θ_{comp} Equation 1

As a result, the calculated new resolver offset value is applied to automatically correct the resolver offset.

The above process of the correction of the resolver offset may be performed at the controller (e.g., a control board into which components used for inverter control are integrated) for controlling overall operation of the inverter in the inverter system.

When the abnormal reverse magnetization state is detected through a diagnosis procedure (e.g., a logic procedure) and determined to be a reverse magnetization state of the permanent magnet of the motor, the motor in the reverse magnetization state may be normally controlled by application of an offset correction value of reverse magnetization.

The magnetization fault of the permanent magnet of the motor is diagnosed using resolver offset correction. Furthermore, upon a determination of reverse magnetization, the motor having the abnormal reverse magnetization is normally controlled by application of the resolver offset correction value calculated in the reverse magnetization state, i.e., the offset correction value of reverse magnetization.

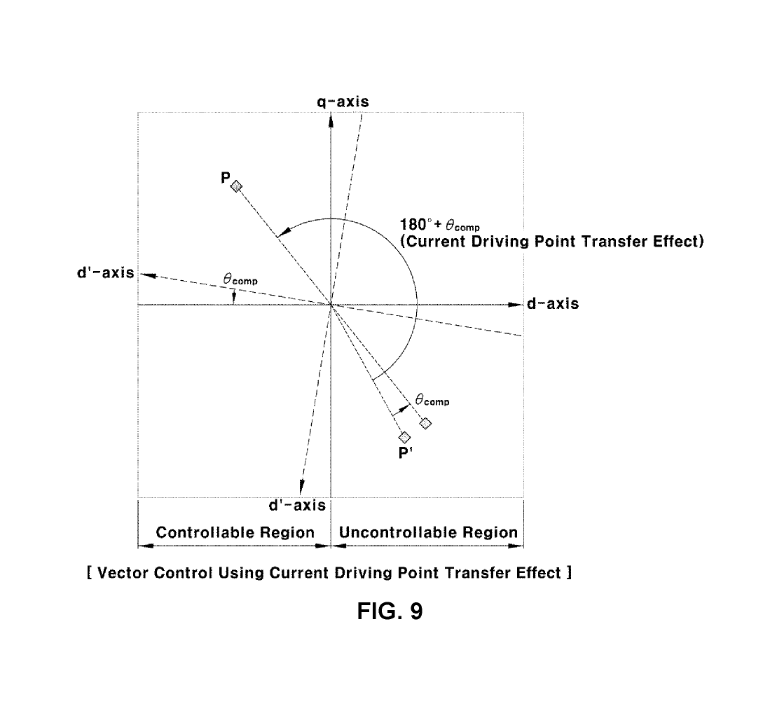

FIG. 8 illustrates a method of correcting reverse magnetization of the rotor of the permanent magnet using the resolver offset. FIG. 9 illustrates vector control using a current driving point transfer effect.

As described above, the permanent magnet of the reversely magnetized motor has an electrical phase difference of 180 degrees relative to the permanent magnet of the normally magnetized motor (FIG. 4).

As illustrated in FIG. 9, upon control of the d-q current vector, the interior permanent magnet synchronous motor includes the controllable region (the second and third quadrants of the d-q control plane) and the uncontrollable region (the first and fourth quadrants). When the current vector is controlled by the conventional manner, current is applied to the uncontrollable region in the d-q control plane.

When the current command is applied to the reversely magnetized motor, the current driving point P′ is determined at the uncontrollable region such that it is impossible to control the motor. Unless the driving point moves, it is impossible to control the motor.

A resolver offset correction has an effect of rotating the d-q control axis. As illustrated in FIG. 8, when a value (180° +θ_{comp}) obtained by adding the phase difference of 180 degrees of the reversely magnetized permanent magnet to the offset correction value θ_{comp} is applied as the resolver offset correction value of the reversely magnetized motor, i.e., the offset correction value of reverse magnetization, as illustrated in FIG. 9, the current driving point may move to the normal control region (the driving point P′ moves to P). Accordingly, the motor having the abnormal reverse magnetization may be normally controlled.

Herein, 180 degrees is a predetermined phase difference of reverse magnetization of the permanent magnet, considering that the permanent magnet of the reversely magnetized motor has an electrical phase difference of 180 degrees relative to the permanent magnet of the normally magnetized motor.

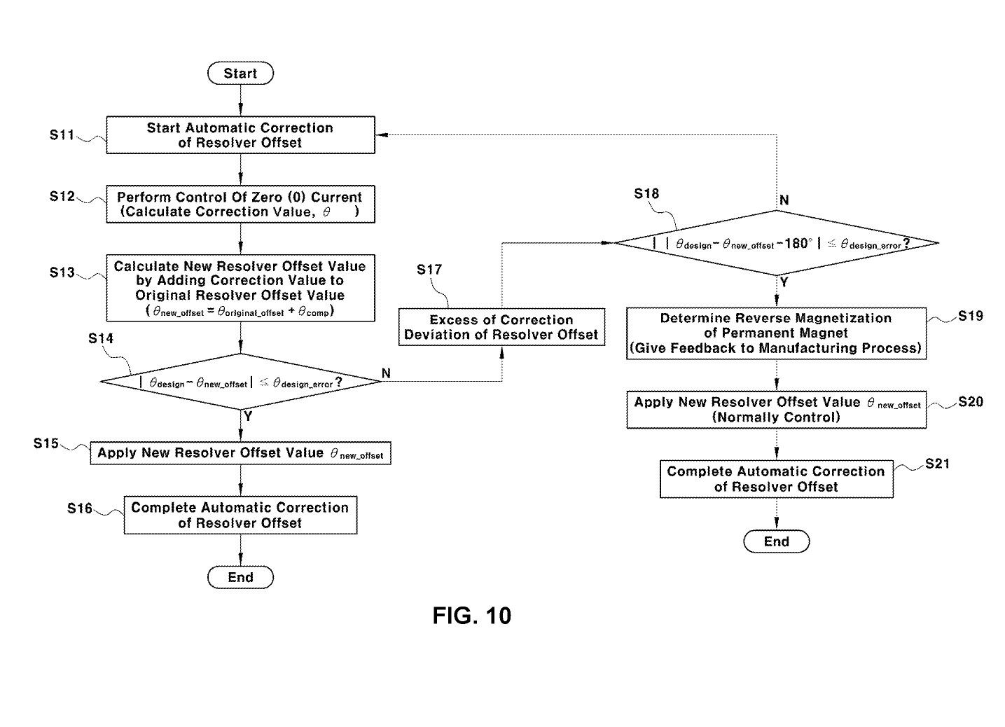

Referring to FIG. 10, the process of detection and correction of reverse magnetization of the permanent magnet of the rotor using resolver offset correction will be described.

An automatic resolver offset correction is started by the controller S11. Upon correction of the resolver offset, the d-axis and q-axis currents are controlled to be zero current (Id=0 A and Iq=0 A) such that the correction value θ_{comp} corresponding to the angle difference between the output d-axis voltage Vd and the output q-axis voltage Vq is calculated by the controller S12.

The original resolver offset value θ_{original}_{_}_{offset} is added to the calculated correction value θ_{comp} by the controller, thereby calculating the new resolver offset value θ_{new}_{_}_{offset} (θ_{new}_{_}_{offset}=θ_{original}_{_}_{offset}+θ_{comp}) S13.

Calculation of the correction value and the new resolver offset value is performed using known resolver offset correction processing.

The new resolver offset value θ_{new}_{_}_{offset} is compared with a predetermined design reference value θ_{design}. When the difference (an absolute value of the difference) between the new resolver offset value θ_{new}_{_}_{offset} and the predetermined design reference value θ_{design}, namely, a correction deviation, is equal to or less than a predetermined design allowable error θ_{design}_{_}ₑᵣᵣₒᵣ, that is, “|θ_{design}−θ_{new}_{_}_{offset}|≦θ_{design}_{_}ₑᵣᵣₒᵣ”, the process of the automatic resolver offset correction is completed by application of the new resolver offset value θ_{new}_{_}_{offset} S14, S15, and

S16.

The new resolver offset value is used to correct the resolver offset. The corrected offset value is used as resolver detection information (e.g., the absolute angular position of the rotor) to control the motor.

Controlling motor driving using the corrected resolver detection information is implemented in accordance with a known process. Detailed description of the process is accordingly omitted.

In step S14, when the correction deviation between the new resolver offset value θ_{new}_{_}_{offset} and the predetermined design reference value θ_{design} is more than the predetermined design allowable error θ_{design}_{_}ₑᵣᵣₒᵣ, namely, “|θ_{design}−θ_{new}_{_}_{offset}|>θ_{design}_{_}ₑᵣᵣₒᵣ”, the controller diagnoses that the correction deviation of the resolver offset is excessive S14 and S17.

Herein, “∥” denotes an absolute value.

When the permanent magnet is mounted at the rotor of the motor in a reversely magnetized state, the controller always diagnoses that the correction deviation of the resolver offset is excessive in step S14 of the resolver offset correction process.

In a case not involving a reversely magnetized state, an excess of the correction deviation of the resolver offset may occur as well. Therefore, after diagnosing the excess correction deviation of the resolver offset, whether the real reverse magnetization or not, may be determined.

In the process of diagnosis of a magnetization fault of the rotor of the motor, e.g., the process of detection of reverse magnetization, a logic procedure using the polarity arrangement of the permanent magnet is used. In the case of the reversely magnetized motor, the reversely magnetized motor having the electrical phase difference of 180 degrees is used.

Thus, after step S14, when excess correction deviation of the resolver offset is diagnosed (step S17), in the case that a value obtained by subtracting the value, which is 180 degrees of the phase difference of reverse magnetization, from the calculated correction deviation |θ_{design}−θ_{new}_{_}_{offset}|, namely, ∥θ_{design}−θ_{new}_{_}_{offset}|−180°|, is equal to or less than the design allowable error θ_{design}_{_}ₑᵣᵣₒᵣ, the permanent magnet is determined to be in a reversely magnetized state S18 and S19.

Upon “∥θ_{design}−θ_{new}_{_}_{offset}|180°|≦θ_{design}_{_}ₑᵣᵣₒᵣ”, the permanent magnet is determined to be in a reversely magnetized state.

Herein, “∥” denotes an absolute value.

180 degrees is the predetermined phase difference of reverse magnetization of the permanent magnet, considering that the permanent magnet of the reversely magnetized motor has an electrical phase difference of 180 degrees relative to the permanent magnet of the normally magnetized motor.

When the value obtained by subtracting the value, which is 180 degrees of the phase difference of reverse magnetization, from the calculated correction deviation |θ_{design}−θ_{new}_{_}_{offset}|, namely, ∥θ_{design}−θ_{new}_{_}_{offset}|−180°|, is more than the design allowable error θ_{design}_{_}ₑᵣᵣₒᵣ, a fault condition is diagnosed due to the excess correction deviation. Accordingly, resolver offset correction is rerun.

Upon ∥θ_{design}−θ_{new}_{_}_{offset}|−180°|>θ_{design}_{_}ₑᵣᵣₒᵣ, the permanent magnet is determined to be diagnosed as in a fault condition due to the excess correction deviation, not to be in a reversely magnetized state, thereby rerunning resolver offset correction. Steps S11, S12, and S13 are rerun to calculate a new resolver offset value.

After the permanent magnet is determined to be in a reversely magnetized state, feedback may be given to a manufacturing process immediately. After the new resolver offset value θ_{new}_{_}_{offset} reflected with the phase difference of 180 degrees is calculated, the process of automatically correcting the resolver offset is completed using the calculated resolver offset value S20 and S21.

The new resolver offset value θ_{new}_{_}_{offset} reflected with the phase difference of 180 degrees is obtained by, as a resolver offset correction value (the offset correction value having reverse magnetization), using the value (180°+θ_{comp}) calculated by adding the phase difference of 180 degrees of the reversely magnetized permanent magnet to the offset correction value θ_{comp} as shown below in Equation 2.

θ_{new}_{_}_{offset}=θ_{original}_{_}_{offset}+(180°+θ_{comp}) Equation 2

When the new resolver offset value θ_{new}_{_}_{offset} applying the resolver offset correction value 180°+θ_{comp} is calculated, the calculated new resolver offset value θ_{new}_{_}_{offset} is applied to complete the automatic correction process of the resolver offset.

The new resolver offset value is used such that the offset of the resolver is corrected (e.g., the reverse magnetization of the rotor of the permanent magnet is corrected) and motor driving is controlled using the corrected offset value as the resolver detection information (e.g., the absolute angular position of the rotor).

Thus, although the motor having the abnormal reverse magnetization is a defective product during a manufacturing process, instead of replacement of the component, the motor may be normally controlled by detection and correction of reverse magnetization.

As apparent from the above description, in the method of diagnosing a magnetization fault of the permanent magnet motor, a reverse magnetization state of the motor may be detected using a logic procedure without the addition of separate hardware. After detecting reverse magnetization, the motor in a reverse magnetization state may be normally controlled through the offset correction of the resolver mounted at the motor.

Various embodiments have been disclosed in this specification and the accompanying drawings. Although specific terms are used herein, the terms are used for describing the various embodiments, and do not limit the meanings and the scope of the present invention recited in the claims. Accordingly, a person having ordinary knowledge in the technical field of the present invention will appreciate that various modifications and other equivalent embodiments can be derived from the above-described embodiments. Therefore, the scope of protection of the present invention should be defined by the appended claims.

What is claimed is:

1. A method of diagnosing a magnetization fault of a permanent magnet motor, the method comprising:
a) calculating a resolver offset value for offset correction of a resolver mounted at a motor;
b) calculating a correction deviation, the correction deviation comprising a difference value between the calculated resolver offset value and a predetermined reference value to compare the calculated correction deviation to an allowable error;
c) comparing a difference value between the calculated correction deviation and a predetermined phase difference value of reverse magnetization of a permanent magnet to the allowable error when the calculated correction deviation is more than the allowable error; and
d) determining that the permanent magnet motor is in a reversely magnetized state when the difference value between the calculated correction deviation and the predetermined phase difference value of reverse magnetization of the permanent magnet is equal to or less than the allowable error.

2. The method according to claim 1, wherein the phase difference value of reverse magnetization is determined to be 180 degrees.

3. The method according to claim 1, wherein, in step a), calculating the resolver offset value comprises adding a resolver offset correction value calculated in a zero current state of the motor, in which d-axis and q-axis currents are controlled to be zero current, to an original resolver offset value.

4. The method according to claim 1, wherein step b) comprises comparing the calculated correction deviation to the allowable error, such that when the correction deviation is equal to or less than the allowable error, the resolver offset value calculated in step a) is used to perform resolver offset correction.

5. The method according to claim 1, wherein step d) comprises, when the permanent magnet of the motor is determined to be in the reversely magnetized state, calculating a new resolver offset value by adding a resolver offset correction value calculated in a zero current state of the motor, in which d-axis and q-axis currents are controlled to be zero current, and the phase difference value of reverse magnetization of the permanent magnet, to an original resolver offset value, wherein the new resolver offset value is used to correct the resolver offset.

6. The method according to claim 5, wherein the phase difference value of reverse magnetization is determined to be 180 degrees.
